(19) United States
(12) Patent Application Publication
(10) Pub. No.: US 2025/0361601 A1
(43) Pub. Date: Nov. 27, 2025

(54) METHOD FOR CONTROLLING SPECIFIC RESISTIVITY AND STRESS OF TUNGSTEN THROUGH PVD SPUTTERING METHOD

(71) Applicant: ULVAC, INC., Chigasaki (JP)

(72) Inventors: Ga Yeong LEE, Pyeongtaek (KR); Hang KANG, Pyeongtaek (KR); Do Hyun OH, Pyeongtaek (KR); Katsuaki NAKANO, Chigasaki (JP); Yukinobu NUMATA, Chigasaki (JP); Taku OKUBO, Chigasaki (JP)

(21) Appl. No.: 18/872,170

(22) PCT Filed: Apr. 7, 2023
(86) PCT No.: PCT/KR2023/004727

§ 371 Date: Dec. 5, 2024

(30) Foreign Application Priority Data
Jun. 22, 2022 (KR) 10-2022-0076055

(51) Int. Cl. C23C 14/35; C23C 14/14; C23C 14/58

(52) U.S. Cl. CPC C23C 14/35; C23C 14/14; C23C 14/58

(57) ABSTRACT

The present invention relates to a method for forming a tungsten (W) film in a semiconductor device, by using a physical vapor deposition (PVD) sputtering method on a semiconductor substrate, the tungsten film forming method comprising: a) a first deposition step of depositing a tungsten film on the semiconductor substrate by using magnetron sputtering with a power density of less than 0.5 W/cm²; b) a step of modifying the surface of the deposited tungsten by performing RF bias processing under an inert gas atmosphere; and c) a second deposition step of additionally depositing a tungsten film on the deposited tungsten film by using magnetron sputtering of a power density of 0.5 W/cm² or more.

### TECHNICAL FIELD

The present disclosure relates to a method of controlling resistivity and stress of a semiconductor substrate film using a physical vapor deposition (PVD) sputtering method, and more particularly, to a method of forming a tungsten (W) film on a semiconductor device using a PVD sputtering method and a tungsten film manufactured by the method.

### BACKGROUND ART

Recently, as the size of various devices is getting smaller, the need for ultra-thin films in semiconductor devices is increasing. Accordingly, metals such as Cu with low resistivity that are currently in use have a problem in that the resistivity increases rapidly as a thickness decreases due to the nature of the material. Therefore, materials with relatively low resistivity such as tungsten (W), ruthenium (Ru), molybdenum (Mo), and rhodium (Rh) are being reviewed for next-generation wiring structures due to miniaturization of semiconductor devices, etc.

Herein, the inventors of the present disclosure have used tungsten (W) to replace existing materials such as Cu, and when depositing a thin film by physical vapor deposition (PVD) sputtering, a seed layer deposition process is repeated through deposition and plasma treatment to improve an initial interface layer, and then a tungsten thin film is grown on the improved interface layer, thereby controlling a grain size and orientation of grains of the deposited tungsten thin film. Through this, it is found that it is possible to ultimately obtain a tungsten thin film with greatly improved resistivity and also control the stress of the thin film.

### DISCLOSURE OF THE INVENTION

### Technical Goals

A general method of depositing tungsten, etc. in a physical vapor deposition (PVD) process of the related art includes forming a metal film in one process step at constant DC power. However, unlike the process of the related art that is performed in one process step, an object of the present disclosure is to perform the plasma treatment by applying only radio-frequency (RF) stage bias after tungsten deposition at low power, and repeatedly perform this process 1 to 4 times to improve a grain size and resistivity of the deposited tungsten.

In addition, through the repeated process, an object thereof is to form stress in a tensile direction while controlling an initial interface of tungsten to obtain a film property having a stress close to 0 in a compressive film.

However, goals to be achieved are not limited to those described above, and other goals not mentioned above are clearly understood by one of ordinary skill in the art from the following description.

### Technical Solutions

According to an embodiment of the present disclosure, there is provided a method of forming a tungsten (W) film of a semiconductor device on a semiconductor substrate using a physical vapor deposition (PVD) sputtering method, the method including
a) first deposition step of depositing a tungsten film on the semiconductor substrate using magnetron sputtering at a power density of less than 0.5 W/cm²;
b) step of modifying a surface of the deposited tungsten by performing radio-frequency (RF) bias treatment under an inert gas atmosphere; and
c) second deposition step of additionally depositing a tungsten film on the deposited tungsten film using magnetron sputtering at a power density of 0.5 W/cm² or more.

According to another embodiment of the present disclosure, there is provided a tungsten film of a semiconductor device manufactured by a method of forming a tungsten film, wherein
the method includes
a) first deposition step of depositing a tungsten film on a semiconductor substrate using magnetron sputtering at a power density of less than 0.5 W/cm²;
b) step of modifying a surface of the deposited tungsten by performing RF bias treatment under an inert gas atmosphere; and
c) second deposition step of additionally depositing a tungsten film on the deposited tungsten film using magnetron sputtering at a power density of 0.5 W/cm² or more, and
the tungsten film has a tungsten film property in that a percentage of grains having a grain size of 0.12 μm or more is 50% or more.

### Effects of the Invention

A method of forming a tungsten according to an embodiment of the present disclosure has the advantage of being able to control a grain size and orientation of grains of a tungsten film to be deposited, by replacing a material such as Cu that has been used in the related art and performing deposition by dividing the PVD process into a first deposition step, a surface modification step, and a second deposition step.

In addition, through this, the grain size of the tungsten film may be increased compared to the PVD process of the related art, and a percentage of grains with (110) orientation may be increased to obtain low resistivity. When the film forming method according to an embodiment of the present disclosure is applied, internal tensile deformation may occur, so that an interplanar distance in each crystal grain becomes different, and thus the stress of the tungsten may also be controlled.

Furthermore, in the tungsten film forming process, the first deposition step and the surface modification step may be performed 1 to 4 times before the second deposition step, or the tungsten film deposition conditions (a direct current (DC) voltage, Ar, Kr flow rate, etc.) may be adjusted to optimally control the effect of reducing the resistivity. A tungsten film obtained accordingly exhibits excellent quality.

It should be understood that the effects of the present disclosure are not limited to the above-described effects, but are construed as including all effects that may be inferred from the configurations and features described in the following description or claims of the present disclosure.

### BRIEF DESCRIPTION OF DRAWINGS

FIG. 1 is a diagram illustrating a tungsten film forming process according to an embodiment of the present disclosure.

FIG. 2 is a diagram schematically comparing a tungsten film forming process and a tungsten film forming process according to an embodiment of the present disclosure.

FIG. 3 is a diagram illustrating a size of resistivity for each number of repetitions of a first deposition step in a tungsten film forming process according to an embodiment of the present disclosure.

FIG. 4 is a diagram illustrating comparison between a process of the related art including only a second deposition step, a process including only first deposition and second deposition steps without performing radio-frequency (RF) bias treatment, and a tungsten film forming process (performing the first deposition step four times) according to an embodiment of the present disclosure.

FIG. 5 is a diagram illustrating a size of resistivity according to direct current (DC) power of a first deposition step and a second deposition step.

FIG. 6 is a diagram illustrating a fraction of tungsten grain sizes obtained through a tungsten film forming process according to an embodiment of the present disclosure.

FIG. 7 is a diagram illustrating results of X-ray diffraction (XRD) measurement of a tungsten film manufactured by a tungsten film forming process according to an embodiment of the present disclosure.

FIG. 8 is a diagram illustrating comparison of results of electron back scatter diffraction (EBSD) measurement between a tungsten film manufactured by a tungsten film forming process according to an embodiment of the present disclosure and a tungsten film manufactured by a process of the related art.

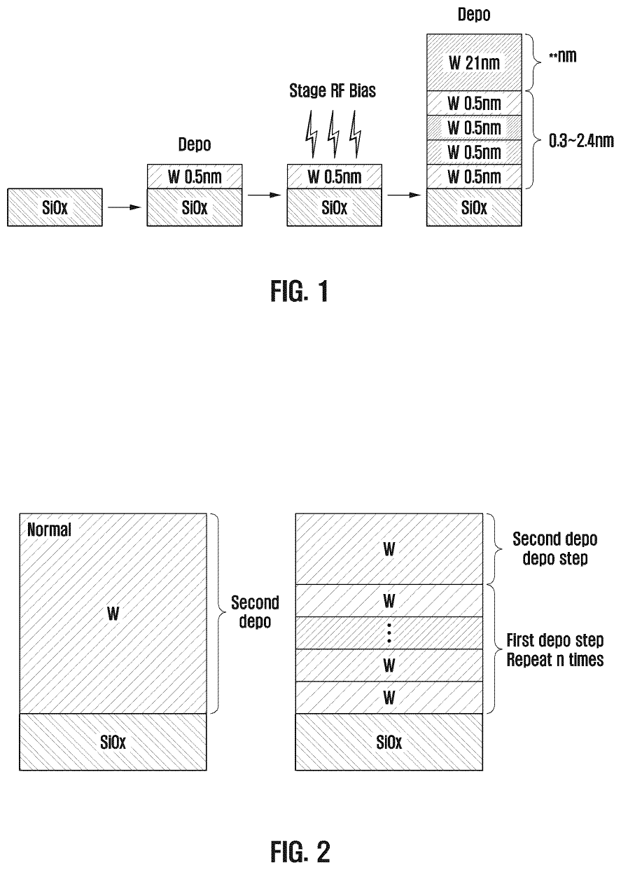

### BEST MODE FOR CARRYING OUT THE INVENTION

Hereinafter, embodiments will be described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

According to an embodiment of the present disclosure, provided is a method of forming a tungsten (W) film of a semiconductor device on a semiconductor substrate using a physical vapor deposition (PVD) sputtering method, the method including
a) first deposition step of depositing a tungsten film on the semiconductor substrate using magnetron sputtering at a power density of less than 0.5 W/cm²;
b) step of modifying a surface of the deposited tungsten by performing radio-frequency (RF) bias treatment under an inert gas atmosphere; and
c) second deposition step of additionally depositing a tungsten film on the deposited tungsten film using magnetron sputtering at a power density of 0.5 W/cm² or more.

In step a) (the first deposition step), a tungsten film may be deposited at a low power density (less than 0.5 W/cm²) using direct current (DC) power and RF power (RF stage bias), and the tungsten film formed on the semiconductor substrate through this may have a thickness of 0.3 to 0.6 nanometers (nm).

When the thickness of the tungsten film formed through the first deposition step is less than 0.3 nm or more than 0.6 nm, a problem that resistivity of the formed tungsten film increases may occur, as shown in Table 3 of examples described below.

In the first deposition step, the DC power is preferably relatively low, specifically less than 1 kW, for example, 0.2 kW to 0.6 kW, and more specifically 0.4 kW. In addition, the RF power applied simultaneously with the DC power may be used in the range of 50 W to 200 W.

Meanwhile, the type of the semiconductor substrate used in the tungsten film formation is not particularly limited as long as it is a wafer substrate that may exhibiting the same process effect, and a wafer of SiO₂ may be used as an example.

In addition, step b) which is a surface modification step of the deposited tungsten may be included after the first deposition step of tungsten in step a).

Step b) may include a process of using an inert gas containing one or more selected from the group consisting of Ar, Kr, Ne and Xe by applying only RF power without applying DC power to form plasma of the gas. At this time, considering the effective viewpoint of the disclosure, it may be preferable to use a Kr gas compared to an Ar gas, but the type is not particularly limited.

In addition, the RF power may be 50 W to 200 W, and the RF bias treatment is performed for about 2 to 10 seconds. It is advantageous that, through this, an interface of the tungsten film may be improved.

Meanwhile, in the method of forming the tungsten film on the semiconductor device according to an embodiment of the present disclosure, steps a) and b) may be performed not only once but up to four times. Through this, the tungsten film that is primarily deposited may be deposited with a thickness of 0.3 nm to 2.4 nm.

In this way, by performing the first deposition step (step a)) and the surface modification step (step b)) one or more times and four or less times, an interface of a seed layer may be improved, the grain size of the manufactured tungsten film may be increased, and the resistivity may be improved.

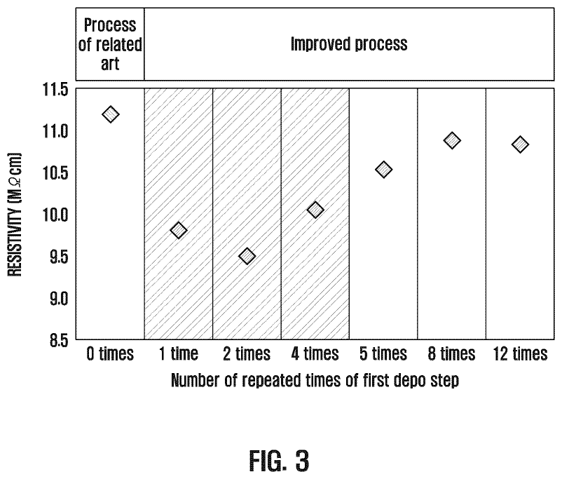

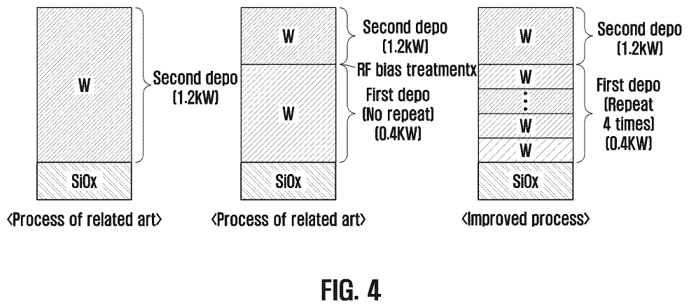

When steps a) and b) are not performed (performed 0 times) or the number of repetitions of steps a) and b) exceeds 4 times, as shown in FIG. 3, the resistivity of the tungsten film increases, resulting in a problem in that it is not suitable for use as a semiconductor device in a small device. In particular, when the number of repetitions of steps a) and b) is 5, 8, and 12, it may be seen that the resistivity is significantly increased to the extent that there is no significant difference from the case where only the second deposition process is performed (steps a) and b) are not performed) (FIG. 3).

In addition, due to the repeated first deposition step and surface modification step, stress may be formed in a tensile direction while controlling an initial interface of tungsten, and a film property having stress close to 0 may be obtained in a compressive film property.

Meanwhile, the method of forming the tungsten film on the semiconductor device according to an embodiment of the present disclosure may include a second deposition step (step c)) of additionally depositing a tungsten film on the deposited tungsten film using magnetron sputtering at a high power density (0.5 W/cm² or more) after performing steps a) and b) repeatedly one to four times.

Through this, the tungsten film may be deposited at one time to a desired thickness, and at this time, the thickness of the tungsten film to be deposited is not significantly limited.

Meanwhile, considering the resistivity of the formed tungsten film, it is preferable that the DC power applied in the first deposition step of step a) is smaller than or equal to the DC power applied in the second deposition step of step c).

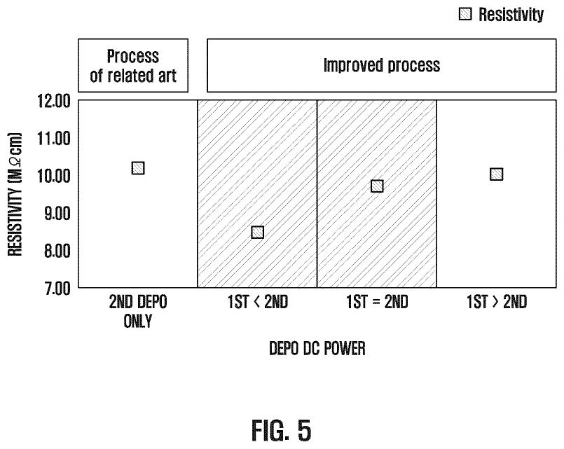

As shown in FIG. 5 below, in the case of a process in which the DC power applied in the first deposition step is greater than the DC power applied in the second deposition step, the resistivity similar to that of the process of the related art that only performs the second deposition step is measured, indicating a somewhat larger resistivity. The specific DC power applied in the second deposition step may be 1.0 kW or more, for example, 1.0 kW or more and less than 3.0 kW, 1.0 kW to 1.6 kW, and more specifically, 1.2 kW.

Steps a), b) and c) are all performed in a chamber in which PVD sputtering may be performed, and it is preferable that a pressure condition of the chamber is 1 Pa or less.

According to another embodiment of the present disclosure, provided is a tungsten film of a semiconductor device manufactured by a method of forming a tungsten film, in which the method includes
a) first deposition step of depositing a tungsten film on a semiconductor substrate using magnetron sputtering at a power density of less than 0.5 W/cm²;
b) step of modifying a surface of the deposited tungsten by performing RF bias treatment under an inert gas atmosphere; and
c) second deposition step of additionally depositing a tungsten film on the deposited tungsten film using magnetron sputtering at a power density of 0.5 W/cm² or more, and
the tungsten film has a tungsten film property in that a percentage of grains having a grain size of 0.12 μm or more is 50% or more.

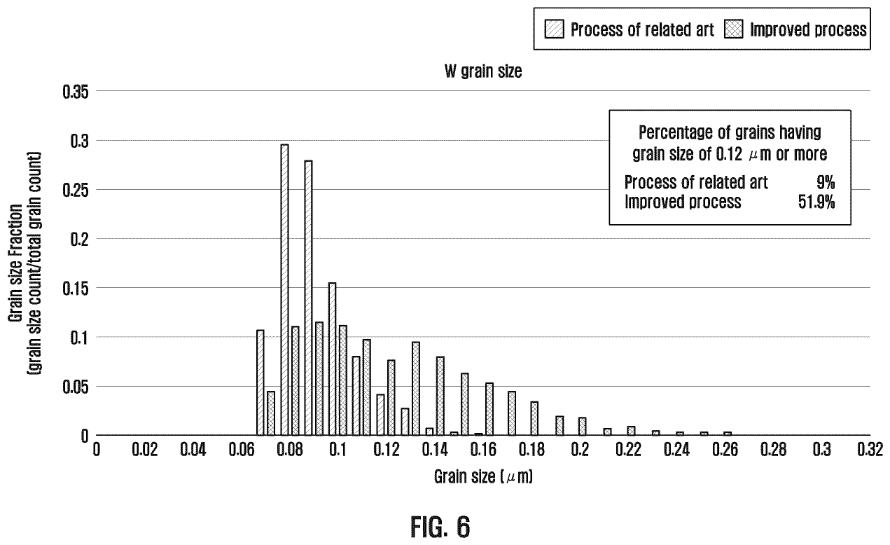

The process of manufacturing the tungsten film of the semiconductor device is substantially the same as the process described in detail above, and unlike the process of the related art that only performs the second deposition step, the percentage of grains having a grain size of 0.12 μm or more in the manufactured tungsten film may be 50% or more. In contrast, in the process of the related art that only performs the second deposition step, the percentage of grains having a grain size of 0.12 μm or more is only about 9%, indicating a significant difference in the tungsten film property (FIG. 6).

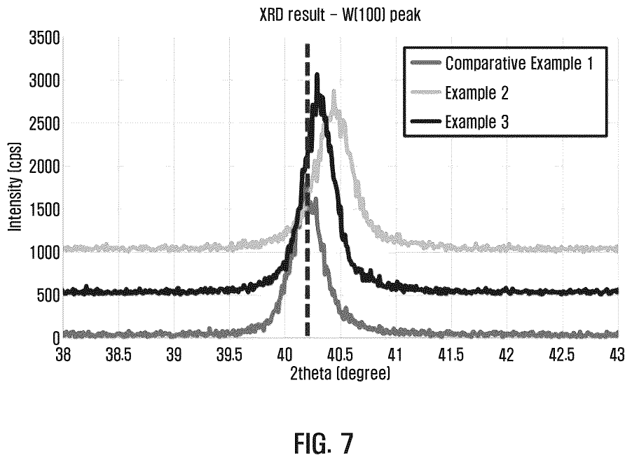

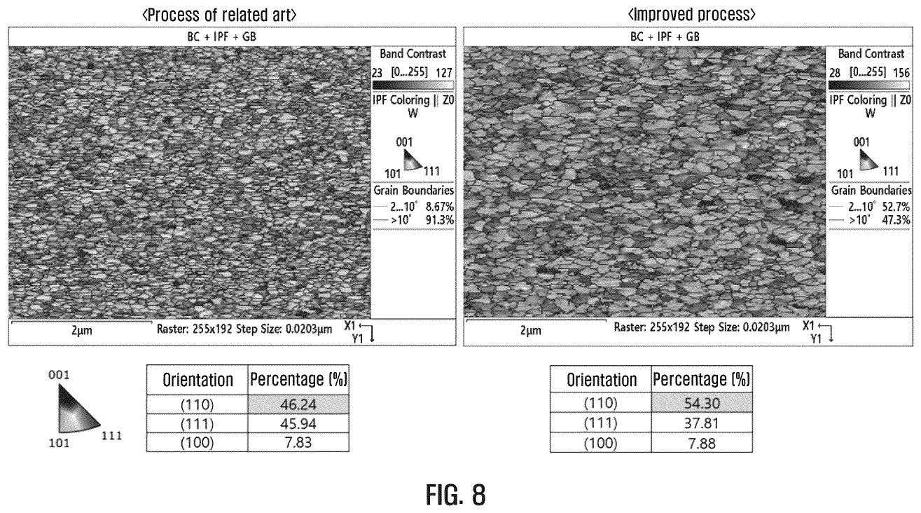

In addition, as shown in FIG. 7, it may be seen that the tungsten film manufactured according to an embodiment of the present disclosure has a (110) peak shift compared to the process of the related art, which indicates that an interplanar distance in crystal grains in the film has changed, resulting in tensile stress in the film. In addition, it may be seen that the number of crystal grains showing (110) orientation increases compared to the process of the related art, and a tungsten film having a percentage of the crystal grains of 50% or more may be obtained, which indicates the effect of the improved resistivity is exhibited (FIG. 8).

Hereinafter, the present disclosure will be described in more detail through examples. The following examples are described for the purpose of illustrating the present disclosure, and the scope of the present disclosure is not limited thereto.

### EXAMPLES

### 1. Method of Forming Tungsten Film of Semiconductor Device

### Example 1

### 1) First Deposition Process of Tungsten (W)

A film was formed based on a PVD sputtering system using experimental equipment, ULVAC ENTRON #1.

A tungsten film having a thickness of 0.5 nm was formed at a low power density (less than 0.5 W/cm²) by simultaneously applying DC power of 0.4 kW and RF bias on a SiO₂ semiconductor substrate.

### 2) RF Bias Treatment Process

An inert gas was supplied into a chamber, only RF power of 50 W to 200 W was applied to a stage for 5 seconds while no DC power was applied to form inert gas plasma, and then the RF bias treatment was performed on the manufactured tungsten film.

### 3) Second Deposition Process of Tungsten (W)

The DC power of 1.2 kW and the RF bias were applied onto the tungsten film subjected to the RF bias treatment to additionally form a tungsten film having a thickness of about 38 nm at a low power density (0.5 W/cm² or more), and a tungsten film having a thickness of 38.52 nm was finally manufactured.

### Examples 2 and 3 (Change of Number of Times First Deposition is Performed)

Tungsten films were manufactured in the same manner as in Example 1 except that the first deposition process of tungsten and the RF bias treatment process were performed two times (Example 2) and four times (Example 3), respectively. As a result, tungsten films having thicknesses of 38.13 nm and 37.74 nm, respectively, were obtained.

### Comparative Example 1 (Normal Deposition)

Only the second deposition process was performed on a SiO₂ substrate using the DC power of 1.2 kW without performing the first deposition process of tungsten (W) and the RF bias treatment process of Example 1. As a result, a film thickness having a total thickness of 38.8 nm was obtained.

### Comparative Example 2

Only the first deposition process and the second deposition process of tungsten (W) were performed on a SiO₂ substrate without performing the RF bias treatment process of Example 1. As a result, a film thickness having a total thickness of 37.3 nm was obtained.

### Comparative Examples 3 to 5 (Change of Number of Times First Deposition is Performed)

Tungsten films were manufactured in the same manner as in Example 1 except that the first deposition process of tungsten and the RF bias treatment process were performed five times (Comparative Example 3), eight times (Example 4), and twelve times (Comparative Example 5), respectively. As a result, tungsten films having thicknesses of 38.2 nm, 38.39 nm, and 37.70 nm, respectively, were obtained.

The resistivity of each of the tungsten films manufactured through Examples 1 to 3 and Comparative Examples 1 to 5 was measured and shown in Table 1 and FIG. 3 below:

TABLE 1

| | | | | Comparative | Comparative | Comparative | Comparative | Comparative |
|---|---|---|---|---|---|---|---|---|
| | Example 1 | Example 2 | Example 3 | Example 1 | Example 2 | Example 3 | Example 4 | Example 5 |
| First | 0.4 | 0.4 | 0.4 | — | 0.4 | 0.4 | 0.4 | 0.4 |
| deposition | | | | | | | | |
| step DC | | | | | | | | |
| power (kW) | | | | | | | | |
| First | 1 | 2 | 4 | — | — | 5 | 8 | 12 |
| deposition | | | | | | | | |
| step | | | | | | | | |
| Number | | | | | | | | |
| of times | | | | | | | | |
| performed | | | | | | | | |
| (times) | | | | | | | | |
| RF bias | ∘ | ∘ | ∘ | x | x | ∘ | ∘ | ∘ |
| treatment | | | | | | | | |
| Second | 1.2 | 1.2 | 1.2 | 1.2 | 1.2 | 1.2 | 1.2 | 1.2 |
| deposition | | | | | | | | |
| step DC | | | | | | | | |
| power (kW) | | | | | | | | |
| Thickness | 38.52 | 38.13 | 37.74 | 38.8 | 37.3 | 38.2 | 38.39 | 37.70 |
| (nm) | | | | | | | | |
| Resistivity | 9.80 | 9.49 | 10.10 | 11.20 | 10.50 | 10.54 | 10.89 | 10.84 |
| (μΩcm) | | | | | | | | |

### 2. Measurement Results of Resistivity for Each DC Power

### Example 4 (DC Power of First Deposition Step<DC Power of Second Deposition Step)

The first deposition step, the RF bias treatment step, and the second deposition step were performed in the same manner as in Example 3, except that a tungsten film having a total thickness of 50.16 nm was obtained by changing the process time in the second deposition step of tungsten (W). As a result, a tungsten film having resistivity of 8.47 μΩcm was manufactured.

### Example 5 (DC Power of First Deposition Step=DC Power of Second Deposition Step)

A tungsten film was manufactured in the same manner as in Example 4, except that the DC power in the first deposition step of tungsten (W) was used as 1.2 kW, and as a result, a tungsten film having a thickness of 51.24 nm and resistivity of 9.71 μΩcm was obtained.

### Comparative Example 6 (DC Power of First Deposition Step>DC Power of Second Deposition Step)

A tungsten film was manufactured in the same manner as in Example 4, except that the DC power in the first deposition step of tungsten (W) was used as 1.6 kW, and as a result, a tungsten film having a thickness of 53.96 nm and resistivity of 10.02 μΩcm was obtained.

### Comparative Example 7 (Normal Deposition)

In order to be compared with Examples 4 and 5 and Comparative Example 6, a tungsten film having a total thickness of 50.14 nm was obtained by performing only the second deposition process on a SiO₂ substrate using the DC power of 1.2 kW without performing the first deposition process of tungsten (W) of the RF bias treatment process. As a result of measuring the resistivity of the tungsten film, it showed 10.18 μΩcm.

The power size and the resistivity of each of the tungsten films manufactured through Examples 4 and 5 and Comparative Examples 6 and 7 are compared and shown in Table 2 and FIG. 5 below:

TABLE 2

| | | | Comparative | Comparative |
|---|---|---|---|---|
| | Example 4 | Example 5 | Example 6 | Example 7 |
| Deposition step power | First deposition < | First deposition = | First deposition > | Performed only |
| | second | second | second | second |
| | deposition | deposition | deposition | deposition |
| First deposition step | 0.4 | 1.2 | 1.6 | — |
| DC power (kW) | | | | |
| First deposition step | 4 | 4 | 4 | 0 |
| Number of times | | | | |
| performed (times) | | | | |
| Second deposition | 1.2 | 1.2 | 1.2 | 1.2 |
| step | | | | |
| DC power (kW) | | | | |
| Thickness (nm) | 50.16 | 51.24 | 53.96 | 50.14 |
| Resistivity (μΩcm) | 8.47 | 9.71 | 10.02 | 10.18 |

### 3. Analysis of Change in Resistivity for Each Film Thickness Per One Time of First Deposition Step

Tungsten films were formed by repeating the first deposition step four times, performing the RF bias treatment, and performing the second deposition step in the same manner as in Example 3 by changing thicknesses of the films per one time of the first deposition step to 0.1 nm, 0.3 nm, 0.4 nm, 0.5 nm, 0.6 nm, 0.9 nm, and 1.0 nm, respectively.

The resistivity thereof was measured and summarized in Table 3 below:

TABLE 3

| | | | | | | | |
|---|---|---|---|---|---|---|---|
| First | 0.1 | 0.3 | 0.4 | 0.5 | 0.6 | 0.9 | 1.0 |
| deposition | | | | | | | |
| step film | | | | | | | |
| thickness | | | | | | | |
| for one | | | | | | | |
| time (nm) | | | | | | | |
| Total film | 39.0 | 38.2 | 39.1 | 39.8 | 40.2 | 41.8 | 41.5 |
| thickness | | | | | | | |
| including | | | | | | | |
| second | | | | | | | |
| deposition | | | | | | | |
| step (nm) | | | | | | | |
| Resistivity | 9.98 | 9.72 | 9.68 | 9.55 | 9.62 | 9.78 | 9.91 |
| (μΩcm) | | | | | | | |

Through this, it may be seen that when the thickness of the tungsten film formed through the first deposition step is less than 0.3 nm or more than 0.6 nm, the resistivity of the formed tungsten film increases.

### 4. Grain Size and Orientation Analysis

### Grain Size and Size-Specific Portion Analysis (FIG. 6)

For the tungsten films formed by the process of the related art (Comparative Example 1) and the improved process (Example 3) according to an embodiment of the present disclosure, electron backscatter diffraction (EBSD) measurement and analysis, which is one of the methods of analyzing the orientation of crystal grains in a specimen by analyzing a diffraction pattern of backscattered electrons, was performed using an ultra-high-resolution field emission scanning electron microscope (FESEM) JSM-IT800 device. The grain size of a surface was calculated through the EBSD and a portion for each grain size was shown (FIG. 6).

As a result, it may be seen that the percentage of grains having a grain size of 0.12 μm or more is only about 9% in the tungsten film manufactured according to Comparative Example 1 (the process of the related art), whereas the percentage of grains having a grain size of 0.12 μm or more is 51.9% in the tungsten film manufactured according to Example 3 (the improved process).

### X-Ray Diffraction (XRD) Measurement and Analysis (FIG. 7 and Table 4)

To analyze the properties of a crystalline material, for the tungsten films formed by the process of the related art (Comparative Example 1) and the improved process (Examples 2 and 3) according to an embodiment of the present disclosure, the XRD analysis was performed using an XRD Rigaku SmartLab (9 kW) device (FIG. 7).

As a result, it may be seen that a position of a W (110) peak of the tungsten film manufactured according to Examples 2 and 3 is shifted compared to the tungsten film manufactured according to Comparative Example 1, and through this, it may be seen that a change in stress has occurred.

TABLE 4

| | Comparative | | |
|---|---|---|---|
| | Example 1 | Example 2 | Example 3 |
| First deposition step | — | 0.4 | 0.4 |
| DC power (kW) | | | |
| First deposition step | — | 2 | 4 |
| Number of times | | | |
| performed (times) | | | |
| RF bias treatment | x | ∘ | ∘ |
| Second deposition step | 1.2 | 1.2 | 1.2 |
| DC power (kW) | | | |
| Stress (MPa) | −1624 | 2114 | 379 |

### Calculation of Grain Orientation and Percentage of Tungsten Film (FIG. 8)

For the tungsten films formed by the process of the related art (Comparative Example 1) and the improved process (Example 3) according to an embodiment of the present disclosure, the EBSD measurement and analysis were performed in the same manner as in FIG. 6. Through the EBSD, the grain orientation and percentage of the orientation were calculated, and an increase in grain size was observed (FIG. 8).

As a result, the percentage of grains having the (110) orientation is 46.24% in the tungsten film manufactured according to Comparative Example 1 (the process of the related art), whereas the percentage of grains having the (110) orientation is 54.30% in the tungsten film formed according to Example 3, indicating that the (110) orientation in the improved process increases by about 8% compared to that in the process of the related art, and the grain size is also larger in the improved process (Example 3).

As described above, although the embodiments have been described with reference to the limited drawings, a person skilled in the art may apply various technical modifications and variations based thereon. For example, suitable results may be achieved if the described techniques are performed in a different order, and/or if the described components are combined in a different manner, or replaced or supplemented by other components or their equivalents.

Therefore, other implementations, other embodiments, and equivalents of the claims are within the scope of the following claims.

1. A method of forming a tungsten (W) film of a semiconductor device on a semiconductor substrate using a physical vapor deposition (PVD) sputtering method, the method comprising:
a) first deposition step of depositing a tungsten film on the semiconductor substrate using magnetron sputtering at a power density of less than 0.5 W/cm²;
b) step of modifying a surface of the deposited tungsten by performing radio-frequency (RF) bias treatment under an inert gas atmosphere; and
c) second deposition step of additionally depositing a tungsten film on the deposited tungsten film using magnetron sputtering at a power density of 0.5 W/cm² or more.

2. The method of claim 1, wherein the tungsten film deposited in step a) has a thickness of 0.3 to 0.6 nanometers (nm).

3. The method of claim 1, wherein steps a) and b) are performed 1 to 4 times before step c).

4. The method of claim 3, wherein the tungsten film deposited through steps a) and b) has a thickness of 0.3 to 2.4 nm.

5. The method of claim 1, wherein direct current (DC) power applied in step a) is less than or equal to DC power applied in step c).

6. The method of claim 1, wherein DC power applied in step a) is less than 1.0 kW, and DC power applied in step c) is 1.0 kW or more and less than 3.0 kW.

7. The method of claim 1, wherein the inert gas in step b) comprises one or more selected from the group consisting of Ar, Kr, Ne, and Xe.

8. The method of claim 1, wherein the RF bias treatment in step b) is performed at 50 W to 200 W for 2 to 10 seconds.

9. The method of claim 1, wherein plasma treatment is performed by applying only RF bias without applying DC power in step b).

10. The method of claim 1, wherein the method is performed in a PVD chamber at 1 Pa or less.

11. A tungsten film of a semiconductor device manufactured by a method of forming a tungsten film, wherein
the method comprises:
a) first deposition step of depositing a tungsten film on a semiconductor substrate using magnetron sputtering at a power density of less than 0.5 W/cm²;
b) step of modifying a surface of the deposited tungsten by performing radio-frequency (RF) bias treatment under an inert gas atmosphere; and
c) second deposition step of additionally depositing a tungsten film on the deposited tungsten film using magnetron sputtering at a power density of 0.5 W/cm² or more, and
the tungsten film has a tungsten film property in that a percentage of grains having a grain size of 0.12 μm or more is 50% or more.

12. The tungsten film of claim 11, wherein a percentage of crystal grains having (110) orientation is 50% or more.
